(19) United States
(12) Patent Application Publication
(10) Pub. No.: US 2009/0268394 A1
(43) Pub. Date: Oct. 29, 2009

(54) HEAT-RADIATING MICROCOMPUTER CASE

(75) Inventor: TA-YANG CHENG, Taipei (TW)

Correspondence Address: SCHMEISER, OLSEN & WATTS, 22 CENTURY HILL DRIVE, SUITE 302, LATHAM, NY, 12110, US

(73) Assignee: KING YOUNG TECHNOLOGY CO., LTD., TAIPEI CITY (TW)

(21) Appl. No.: 12/111,227

(22) Filed: Apr. 29, 2008

(51) Int. Cl. G06F 1/20; H05K 7/20

(52) U.S. Cl. 361/679.54

(57) ABSTRACT

A heat-radiating microcomputer case includes a base having a bottom wall and two upright side walls, a top cover having a plurality of radiating fins formed on a top surface thereof, and a system unit located below a bottom surface of the top cover. Each of the two upright side walls of the base has a free edge with an insertion channel formed along an outer corner thereof. The top cover has two downward extended insertion sections slidably fitted in the insertion channels on the base to detachably assemble to the base. The system unit includes a circuit board having a heat-producing electronic element arranged on an upper side thereof to contact with the bottom surface of the top cover, so that heat produced by the electronic element may be transferred to the large-area top cover and dissipated into ambient air quickly.

### FIELD OF THE INVENTION

The present invention relates to a heat-radiating microcomputer case, and more particularly to a heat-radiating microcomputer case which includes a top cover having a plurality of radiating fins to provide a large contact area with ambient air, allowing heat produced by electronic elements in the microcomputer case in contact with the top cover to be directly transferred to the radiating fins of the top cover and quickly dissipated into ambient environment.

### BACKGROUND OF THE INVENTION

conventionally, a microcomputer case has a motherboard installed therein, on which a central processing unit is mounted and is a main electronic element in the microcomputer that produces heat during the operation thereof. To dissipate the heat produced by the central processing unit, heat-radiating fins are attached to the central processing unit and a fan is arranged above the heat-radiating fins. The heat-radiating fins absorb the heat produced by the central processing unit, so that the heat is distributed over a larger contact area provided by the radiating fins. The fan blows airflows to the heat-radiating fins to carry away the heat in different directions.

However, in addition to the central processing unit, there are also other components on the motherboard that produce heat during the operation thereof. Moreover, the microcomputer case defines a closed inner space. Therefore, the heat produced by the central processing unit as well as other components of the microcomputer is trapped in the closed inner space of the microcomputer case and could not be fully dissipated from of the case. Instead, the heat will stagnate and circulate inside the case. This often leads to an overheated central processing unit that has reduced working efficiency or even results in a failed microcomputer.

It is therefore tried by the inventor to develop a heat-radiating microcomputer case that enables heat produced by the central processing unit to be directly and quickly dissipated from the microcomputer case into ambient air.

### SUMMARY OF THE INVENTION

A primary object of the present invention is to provide a heat-radiating microcomputer case, which provides a large contact area with ambient air and allows heat produced by heat-producing electronic elements in the microcomputer case to be directly transferred to the microcomputer case and quickly dissipated into the ambient air.

To achieve the above and other objects, the heat-radiating microcomputer case according to the present invention includes a base having a bottom wall and two upright side walls, a top cover having a plurality of radiating fins formed on a top surface thereof, and a system unit located below a bottom surface of the top cover. Each of the two upright side walls of the base has a free edge with an insertion channel formed along an outer corner thereof. The top cover has two downward extended insertion sections slidably fitted in the insertion channels on the base to thereby detachably assemble to a top of the base. The system unit includes a circuit board having a heat-producing electronic element arranged on an upper side thereof to contact with the bottom surface of the top cover, so that heat produced by the electronic element is directly transferred to the large-area top cover and the radiating fins thereon, and dissipated into ambient air quickly. On a lower side of the circuit board, there is provided a storage unit, a connection port, a plurality of electronic elements, and a plurality of push keys.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is an exploded perspective view of a heat-radiating microcomputer case according to a first embodiment of the present invention;

FIG. 2 is an assembled view of FIG. 1;

FIG. 3 is a sectional view taken along line A-A of FIG. 2; and

FIG. 4 is an enlarged view of the circled area of FIG. 3.

### DETAILED DESCRIPTION OF THE PREFERRED EMBODIMENTS

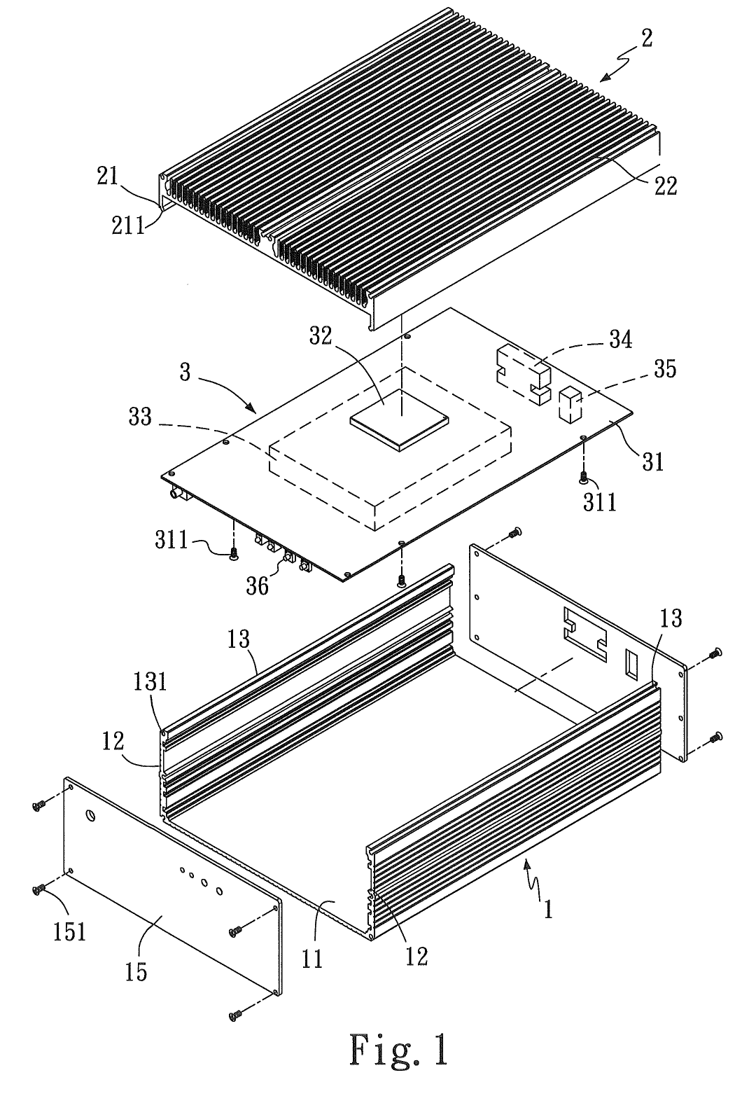

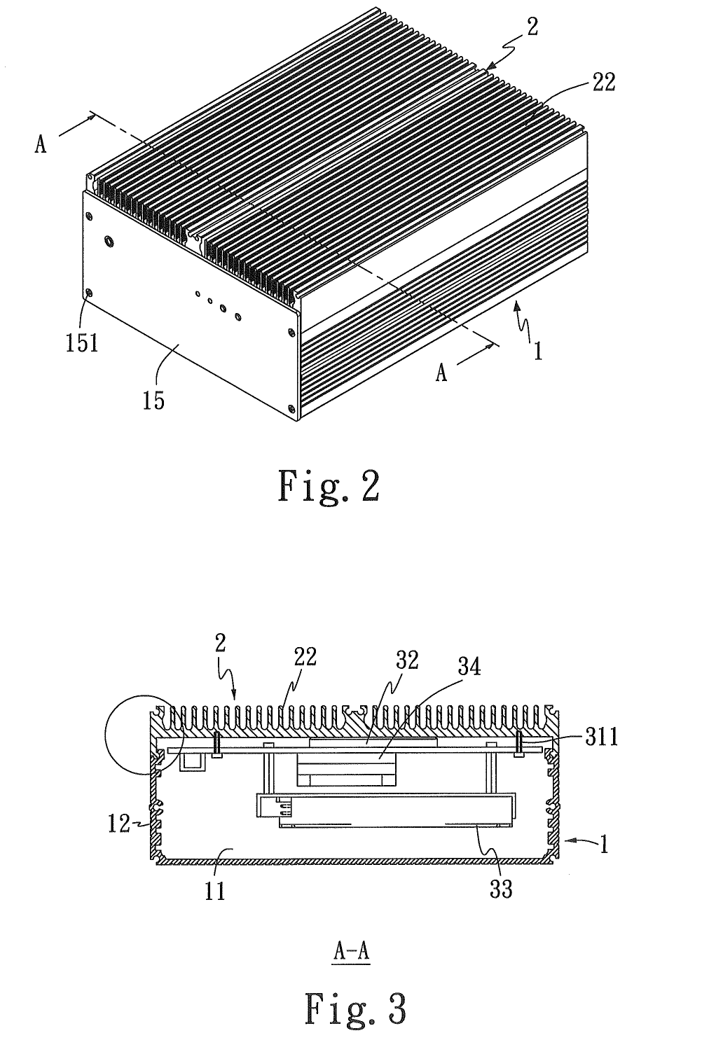

Please refer to FIGS. 1 and 2 that are exploded and assembled perspective views, respectively, of a heat-radiating microcomputer case according to a first embodiment of the present invention, and to FIG. 3 that is a sectional view taken along line A-A of FIG. 2. As shown, the heat-radiating microcomputer case of the present invention includes a base 1, a top cover 2 detachably assembled to a top of the base 1, and a system unit 3.

The base 1 includes a bottom wall 11 and two side walls 12 separately upward perpendicularly extended from two lateral edges of the bottom wall 11. Each of the two upright side walls 12 has a free edge, and an insertion channel 13 formed along an outer corner of the free edge. The insertion channel 13 has a bottom formed into a concave-sectioned recess 131.

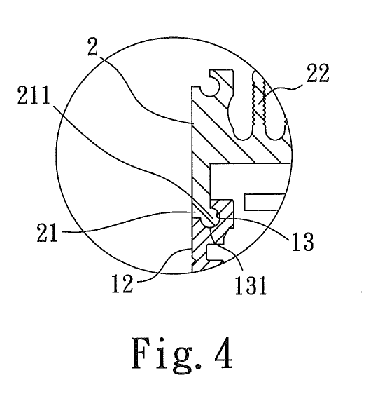

The top cover 2 has two side walls downward extended from two lateral edges thereof to form an insertion section 21 each. The insertion section 21 has a lower edge formed into a round-sectioned projection 211 for correspondingly engaging with the concave-sectioned recess 131 of the insertion channel 13, as can be clearly seen from FIG. 4 that is an enlarged view of the circled area in FIG. 3. In addition, a plurality of radiating fins 22 is formed on a top surface of the top cover 2.

The system unit 3 is fixed to a bottom surface of the top cover 2. The system unit 3 includes a circuit board 31. A central processing unit 32, which is an electronic element producing the largest part of heat in the microcomputer case, is arranged on an upper side of the circuit board 31 to contact with the bottom surface of the top cover 2. On a lower side of the circuit board 31, there are arranged a storage unit 33, a connection port 34, electronic elements 35, and a plurality of push keys 36.

To assemble the heat-radiating microcomputer case of the present invention, the circuit board 31 of the system unit 3 is fixed to the bottom surface of the top cover 2 by means of fastening elements 311. Then, the insertion sections 21 of the top cover 2 are slidably fitted into the insertion channels 13 on the base 1 with the round-sectioned projections 211 slidably held in the concave-sectioned recesses 131 of the insertion channels 13. Thereafter, two end panels 15 are separately locked to front and rear open ends of the base 1 by means of fastening elements 151, so as to fix the top cover 2 to the top of the base 1. With the above arrangements, the central processing unit 32 arranged on the upper side of the circuit board 31 is in direct contact with the bottom surface of the top cover 2. In addition, the radiating fins 22 on the top cover 2 provide a large contact area with the ambient air. Therefore, when the system unit 3 works, heat produced by the central processing unit 32 is directly transferred from the bottom surface of the top cover 2 to the radiating fins 22 on the top surface of the top cover 2, and is then quickly dissipated from the top cover 2 and the radiating fins 22 into the ambient air outside the microcomputer case.

According to a second embodiment of the present invention, a plurality of radiating fins (not shown) is formed on the two upright side walls 12 of the base 1, the system unit 3 is fixed to the bottom wall 11 of the base 1, the insertion sections 21 of the top cover 2 are slidably fitted in the insertion channels 13 of the base 1 with the round-sectioned projections 211 held in the concave-sectioned recesses 131 of the insertion channels 13, and the two end panels 15 are separately locked to the front and rear open ends of the base 1 by means of fastening elements 151 to thereby fix the top cover 2 to the base 1. With these arrangements, the heat produced by the central processing unit 32 is transferred to the radiating fins on the base 1 and quickly dissipated into the ambient air outside the microcomputer case.

According to a third embodiment of the present invention, the circuit board 31 of the system unit 3 is fixed to the bottom surface of the top cover 2 by means of fastening elements 311; the base 1 includes a bottom wall 11 and two flat side walls 12 separately upward perpendicularly extended from two lateral edges of the bottom wall 11; and the top cover 2 has two flat insertion sections which are directly locked onto the upright side walls 12 of the base 1 by fastening elements to thereby fix the top cover 2 to the base 1. Again, two end panels 15 are separately locked to front and rear open ends of the base 1 by means of fastening elements 151, so that the top cover 2 is immovably held to the base 1.

The heat-radiating microcomputer case of the present invention effectively overcomes the heat dissipation problem in the conventional microcomputer because the top cover or the base of the microcomputer case is provided with a plurality of heat radiating fins and is in direct contact with the heat-producing central processing unit, allowing heat produced by the central processing unit and other heat-producing elements in the microcomputer case to be directly transferred to the case that has a large contact area with the ambient air, and quickly dissipated into the ambient environment without being accumulated inside the microcomputer case. Therefore, the present invention is improved and more practical for use to meet most consumers' requirements.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat-radiating microcomputer case, comprising:
a base having a bottom wall and two side walls separately upward perpendicularly extended from two lateral edges of the bottom wall;
a top cover being detachably assembled to a top of the base, and having a plurality of radiating fins formed on a top surface thereof; and
a system unit being arranged below a bottom surface of the top cover, the system unit including at least a circuit board, on an upper side of which a heat-producing electronic element is arranged to contact with the bottom surface of the top cover.

2. The heat-radiating microcomputer case as claimed in claim 1, further comprising two end panels being separately fixed to front and rear open ends of the base.

3. The heat-radiating microcomputer case as claimed in claim 1, wherein each of the upright side walls of the base has a free edge and an insertion channel formed along an outer corner of the free edge, and the insertion channel has a bottom formed into a concave-sectioned recess.

4. The heat-radiating microcomputer case as claimed in claim 1, wherein the top cover has two insertion sections separately downward extended from two lateral edges thereof, and the insertion sections each have a lower edge formed into a round-sectioned projection.

5. The heat-radiating microcomputer case as claimed in claim 1, wherein the system unit is fixed to the bottom surface of the top cover by means of fastening elements.

6. The heat-radiating microcomputer case as claimed in claim 1, wherein each of the upright side walls of the base has a free edge and an insertion channel formed along an outer corner of the free edge, and the insertion channel has a bottom formed into a concave-sectioned recess, and the top cover has two insertion sections separately downward extended from two lateral edges thereof for slidably fitting in the insertion channels.

7. The heat-radiating microcomputer case as claimed in claim 1, wherein on a lower side of the circuit board, there is arranged a storage unit, a connection port, a plurality of electronic elements, and a plurality of push keys.

8. The heat-radiating microcomputer case as claimed in claim 1, wherein the heat-producing electronic element is a central processing unit.
